(19) United States
(12) Patent Application Publication
(10) Pub. No.: US 2008/0144262 A1
(43) Pub. Date: Jun. 19, 2008

(54) PORTABLE ELECTRONIC DEVICE WITH REPLACEABLE OPERATION PANELS

(75) Inventor: Chang-Chin Lai, Taipei (TW)

Correspondence Address: WORKMAN NYDEGGER, 60 EAST SOUTH TEMPLE, 1000 EAGLE GATE TOWER, SALT LAKE CITY, UT, 84111, US

(73) Assignee: INVENTEC CORPORATION, Taipei (TW)

(21) Appl. No.: 11/612,599

(22) Filed: Dec. 19, 2006

(51) Int. Cl. G06F 1/16; H05K 5/00

(52) U.S. Cl. 361/680; 361/679; 361/681

(57) ABSTRACT

A portable electronic device with replaceable operation panels includes a main body and several replaceable operation panels to be replaced. The panels can meet different operation requirements. The replaceable operation panels are selectively installed in the operation region of the main body and electrically connected to the main body. Because different panels can meet different operation modes and directly provide the best operation for different requirements, they enable the user getting easier operation of the electronic device.

### BACKGROUND OF THE INVENTION

1. Field of Invention

The invention generally relates to the operation panel of an electronic device, and in particular relates to a portable electronic device equipped with different operation panels to be replaced according to different requirements.

2. Related Art

Portable electronic devices, such as portable computers, Personal Digital Assistants (PDAs), mobile phones and so on, perform different functions according to different software, such as word processing, game, multimedia and so on. Take portable computer as an example, the operation and software execution is made though keyboard and cursor controlling device (such as mouse or touch pad) for selecting the software or data to be processed. The above operation is convenient in word processing or Internet application. However, for games or multimedia playing, this way is not suitable. When a user wants to play game, the keyboard and cursor controlling device cannot suit kinds of game operation. Most games require an additional joystick to get the best operation mode.

For multimedia playing, the user has to select icons on the display through a cursor controlling device. It is quite different from direct pressing of control buttons of a common multimedia player. Though the user may assign hotkeys on the keyboard, the keyboard doesn't have label or printing directly correspondent to the multimedia operation functions. Therefore, the user has to spend extra time to remember the correspondent hotkey functions. At present, there are so-called multimedia computers that are equipped with a group of multimedia key buttons on the chassis of the computer for processing multimedia files. However, for portable electronic devices that are usually of a smaller size, it is not easy to include extra key buttons. There are also remote controller bundled with software that can be used like remote controllers of common electrical appliances or multimedia players. However, when being applied to portable electronic devices, the remote controller are easy to be lost. Therefore, how to improve the existing control panels of portable electronic devices to meet with different operation demands becomes an important technical issue.

In addition, the conventional operation panels are integrated into the structure of electronic devices. It is extremely inconvenient that disassembling the shells are required when installing or disassembling the panels. It is also a technical problem.

### SUMMARY OF THE INVENTION

In view of the foregoing, the object of the invention is to provide a portable electronic device equipped with replaceable panels to meet with different requirements, for solving the problems of portable electronic devices with a single panel that are unable to meet with different operation modes.

In order to achieve the aforesaid object, a portable electronic device with replaceable operation panels is provided, which includes a main body having an operation region and a plurality of panels. The panels can meet with different operation requirements, and the panels are selectively installed in the operation region according to the requirements of operation and electrically connected to the main body. Because different panels can meet with different operation modes and directly provide the best operation for different requirements, they enable the user getting easier operation of the electronic device.

The advantages of the present invention are that the panels can be replaced according to requirements, so that best operation can be obtained when different functions are performed by the electronic device. Further, the panels can be easily removed from the main body of the electronic device and replaced by another panel. It also solves the problem of conventional panel that was difficult to be disassembled.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given hereinbelow. However, this description is for purposes of illustration only, and thus is not limitative of the invention, wherein:

FIG. 1A is an exploded view of a first embodiment of the invention;

FIG. 1B is a perspective view of the first embodiment of the invention;

FIG. 2A is an exploded view of a second embodiment of the invention;

FIG. 2B is a perspective view of the second embodiment of the invention;

FIG. 3A is an exploded view of a third embodiment of the invention; and

FIG. 3B is a perspective view of the third embodiment of the invention.

### DETAILED DESCRIPTION OF THE INVENTION

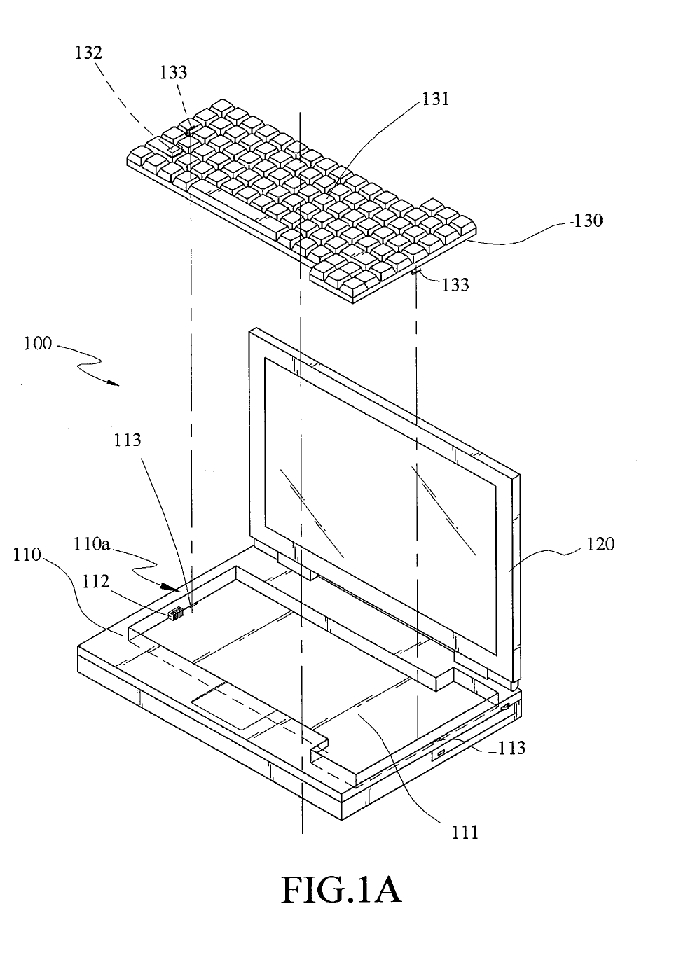

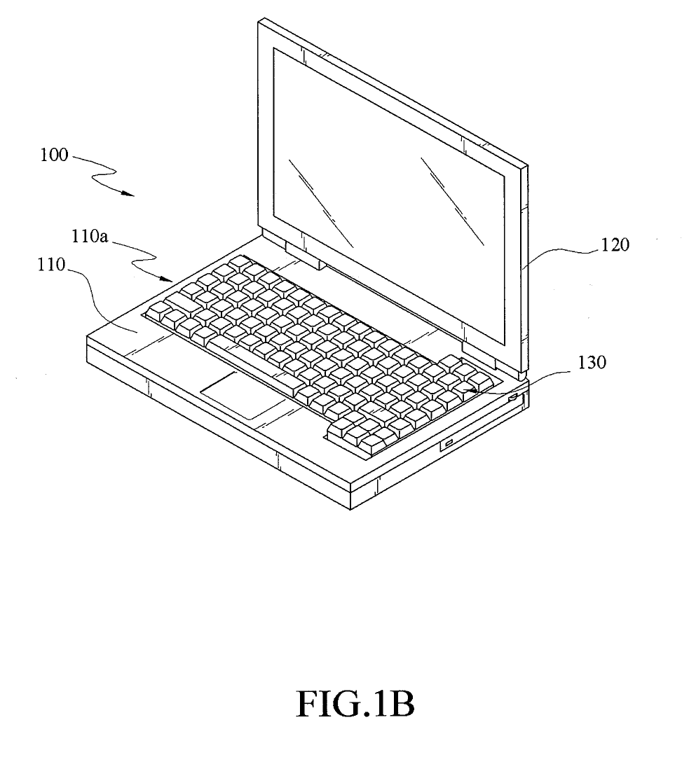

As shown in FIG. 1A and FIG. 1B, a portable electronic device with replaceable operation panels of a first embodiment of the invention is provided. The electronic device 100 is incorporated with different replaceable operation panels to meet with different operation requirements. The electronic device 100 can be a portable computer, a PDA, a Barebone computer, a mobile phone and so on. In the first embodiment, the electronic device 100 is a portable computer having a main body 110 and a display 120 pivoted on the main body 110. The main body 110 has an operation region 110a on one side. The operation region 110a is concavely formed with a cavity 111 for receiving the replaceable operation panels. In addition, the main body 110 has a first connector 112 in the cavity 111, and the main body 110 is formed with two latch holes 113 on the bottom of cavity 111 Certainly, the panels can also be directly installed in the operation region 110a without the cavity 111 formed thereon.

Still referring to FIG. 1A and FIG. 1B, an exploded view and a perspective view of the first embodiment of the invention, when the portable computer is required for word processing or general computer operations, a keyboard panel 130 is used. The keyboard panel 130 includes a standard keyboard 131 for text and data input. The keyboard panel 130 further has a second connector 132 corresponding to the first connector 112 of the main body 110, wherein the second connector 132 is utilized to be connected with the first connector 112 for connecting the keyboard panel 130 to the main body 110. And the keyboard panel 130 is formed with two hooks 133 respectively on two opposite edges of the keyboard panel 130 corresponding to the two latch holes 113. The latch holes 113 of the main body 110 are utilized to be engaged with the hooks 133 for fixing the keyboard panel 130 to the main body 110.

When the keyboard panel 130 is installed in the cavity 111 of the main body 110, the latch holes 113 are engaged with the hooks 133 to fix the keyboard panel 130 in the operation region 110a. Meanwhile, the keyboard panel 130 is electrically connected to the main body 110 by interconnecting the first connector 112 and the second connector 132, for carrying out general computer operations. The keyboard panel 130 also has an identification circuit, when the first connector 112 and the second connector 132 are interconnected, the main body 110 identifies the operation mode provided by the keyboard panel 130 via the identification circuit and then transforms the user interface of the electronic device 100 corresponding to the operation mode provided by the keyboard panel 130. The keyboard panel 130 is detachable from the main body 110. When the keyboard panel 130 does not meet with the operation requirement of the electronic device 100, the keyboard panel 130 can be detached from the main body by disconnecting the first connector 112 and the second connector 132 and ejecting the hooks 133 from the latch holes 113 simultaneously.

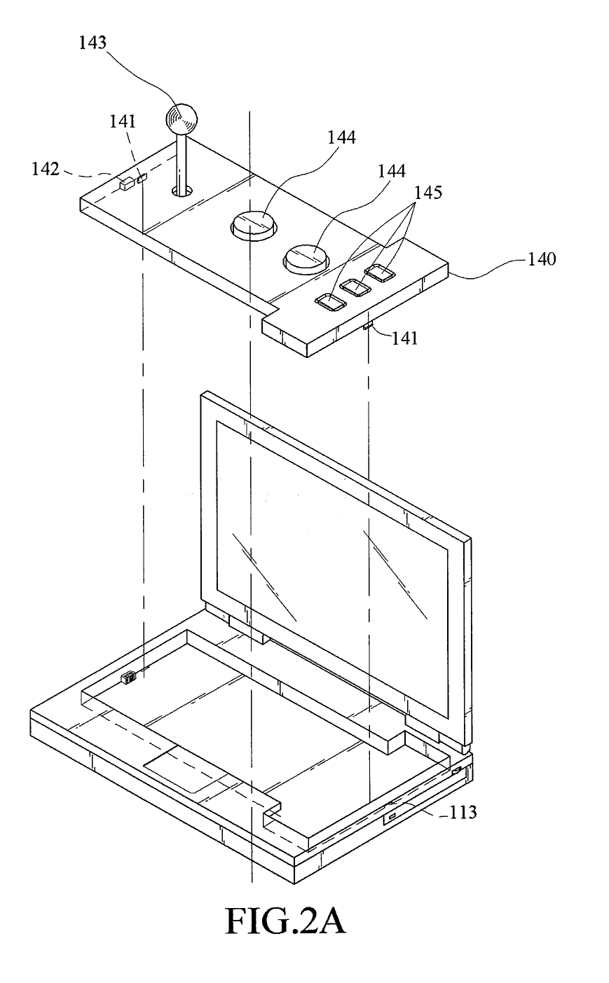

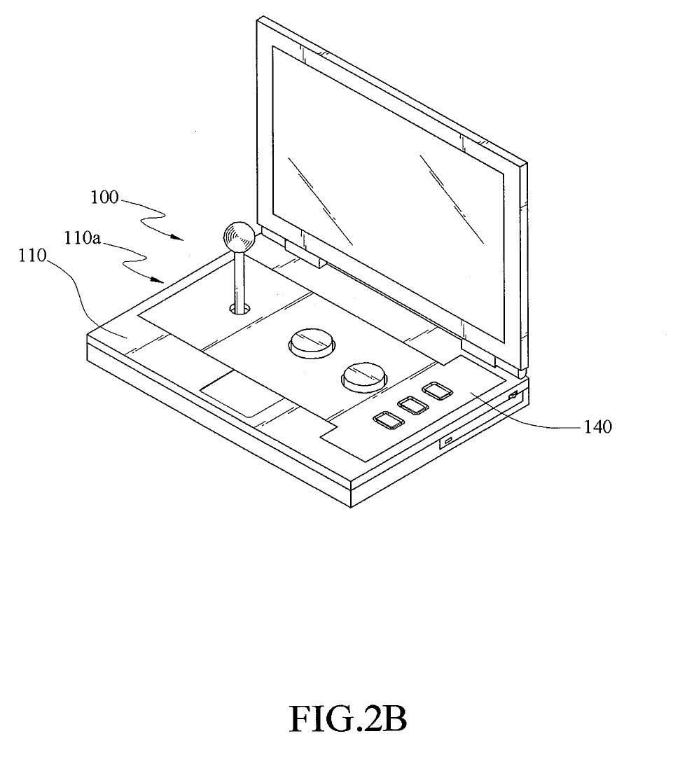

As shown in FIG. 2A and FIG. 2B, an exploded view and a perspective view of the second embodiment of the invention, when the electronic device 100 is required for game functions, a game panel 140 is used. The game panel 140 is provided for playing game, instead of keyboard panel 130. The bottom of the game panel 140 has a second connector 142 and two hooks 141. When the game panel 140 is installed in the cavity 111 of the main body 110, the latch holes 113 are engaged with the hooks 141 to fix the game panel 140 in the operation region 110a. Meanwhile, the game panel 140 is electrically connected to the main body 110 by interconnecting the first connector 112 and the second connector 142, for providing game-playing interfaces, such as joystick 143, game buttons 144, function keys 145, and so on, to meet with the game-playing requirements. Therefore, the game-playing interfaces are directly equipped on the electronic device 100. The game panel 140 also has an identification circuit, when the first connector 112 and the second connector 142 are connected to each other, the main body 110 identifies the operation mode provided by the game panel 140 via the identification circuit, and then transforms the user interface of the electronic device 100 corresponding to the operation mode provided by the game panel 140 and adjusts the operation system of the electronic device 100 to adopt the game panel 140. Further, a game list applicable to the game panel 140 can be preset so that when the electronic device 100 with the game panel 140 is turned on, a correspondent game list can be loaded automatically for the user to select a game from the game list and to play the game.

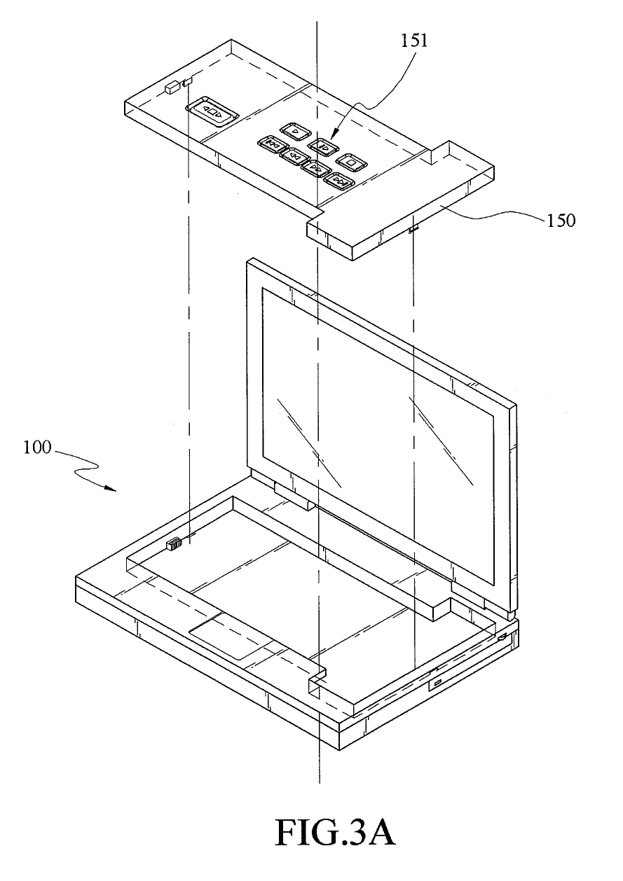

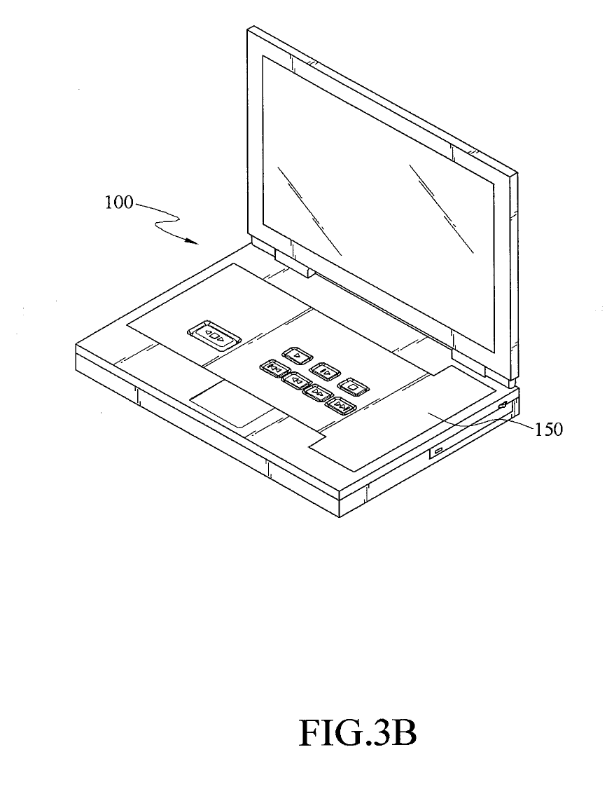

Referring to FIG. 3A and FIG. 3B, a third embodiment of the invention is provided. In the third embodiment, the electronic device 100 is equipped with multimedia panel 150 to be used as a multimedia player. In general, when playing multimedia files with the electronic device 100, such as a portable computer, a PDA, a Barebone computer, a mobile phone and so on, the user has to select icons on the display 120 through a cursor controlling device. It is not so convenient in operation. Though the user may assign hotkeys on the keyboard, but these hotkeys doesn't have label or printing directly correspondent to the multimedia operation functions. Therefore, the user has to spend extra time to remember the correspondent hotkey functions. Therefore, the third embodiment provides a multimedia panel 150 for playing multimedia files.

The multimedia panel 150 includes multimedia keys 151 marked with characters or notations to denote specific functions, such as file select, play, pause, stop, forward, backward and so on, for the user to operate easily. Further, the multimedia panel 150 can be incorporated with an operation system specially designed for multimedia operation. When the multimedia panel 150 is installed to the main body, the electronic device 100 can be turned on with the multimedia operation system only, instead of its original operation system, so as to speed up the starting without executing excessive software. It makes the operation of the electronic device 100 much similar to a multimedia player.

The invention makes it possible to detach the panel of the electronic device 100 and replace with another panel. It provides operation convenience to the users without abandoning individual function when integrating different functions into the electronic device 100. Also, the panel assembling and replacement is easy that there is no need to disassemble the whole electronic device 100 when detaching and replacing the panel.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A portable electronic device with replaceable operation panels, comprising:
a main body, having an operation region; and
a plurality of replaceable operation panels, selectively installed in said operation region and connected to said main body, for operating said electronic device with different operations.

2. The portable electronic device with replaceable operation panels according to claim 1, wherein said electronic device further includes a display pivoted on said main body.

3. The portable electronic device with replaceable operation panels according to claim 1, wherein said operation region is formed with a cavity for receiving said replaceable operation panels.

4. The portable electronic device with replaceable operation panels according to claim 1, wherein said main body further includes a first connector and each of the replaceable operation panels further includes a second connector respectively, wherein the first connector is utilized to be connected with the second connector for connecting said replaceable operation panel to said main body.

5. The portable electronic device with replaceable operation panels according to claim 1, wherein said main body is further formed with a latch hole and each of the replaceable operation panels further is formed with a correspondent hook respectively, wherein the latch hole is utilized to be engaged with the hook for fixing said panel to said main body.

6. The portable electronic device according to claim 1, wherein the replaceable operation panels are selected from the group consisting of a keyboard panel, a game panel and a multimedia panel.

7. A portable electronic device, comprising:
a main body, having an operation region and a first connector; and
an operation panel having a second connector, wherein the operation panel is installed in said operation region and electrically connected to said main body by interconnecting the first connector and the second connector so that the operation panel is detachable form the main body.

8. The portable electronic device according to claim 7, wherein the operation panel is selected from the group consisting of a keyboard panel, a game panel and a multimedia panel.

9. The portable electronic device according to claim 7, wherein said operation region is formed with a cavity for receiving said operation panel.

10. The portable electronic device according to claim 7, wherein said main body is further formed with a latch hole and the operation panel further formed a correspondent hook respectively, wherein the latch hole is utilized to be engaged with the hook for fixing said operation panel to said main body.

11. The portable electronic device according to claim 7, wherein the portable electronic device is selected from the group consisting of a portable computer, a PDA, a barebone computer and a mobile phone.
